(19) United States
(12) Patent Application Publication
(10) Pub. No.: US 2025/0294702 A1
(43) Pub. Date: Sep. 18, 2025

(54) THERMALLY-ENHANCED STRUCTURE FOR IMMERSION COOLING

(71) Applicant: Micron Technology, Inc., Boise, ID (US)

(72) Inventors: Chen Yu Huang, Taichung City (TW); Chong Leong Gan, Taichung City (TW)

(21) Appl. No.: 19/076,295

(22) Filed: Mar. 11, 2025

Related U.S. Application Data
(60) Provisional application No. 63/564,270, filed on Mar. 12, 2024.

(51) Int. Cl. H05K 7/20; H05K 1/02

(52) U.S. Cl. CPC H05K 7/20236; H05K 1/0203; H05K 7/20272; H05K 7/20772; H05K 7/20836; H05K 2201/064; H05K 2201/10159

(57) ABSTRACT

A memory device for use in immersion cooling comprises a printed circuit board, one or more surface-mounted devices coupled to the printed circuit board, and one or more coolant outlets coupled to the printed circuit board to deliver coolant to the one or more surface-mounted devices. A system for cooling electronic devices comprises a tank for receiving a coolant liquid into which the electronic devices can be immersed in use, a manifold comprising a fluid inlet coupleable to a supply of pressurized coolant and a plurality of spigots to deliver coolant liquid to coolant outlets located at or on printed circuit board.

### PRIORITY APPLICATION

This application claims the benefit of priority to U.S. Provisional Application Ser. No. 63/564,270, filed Mar. 12, 2024, which is incorporated herein by reference in its entirety.

### BACKGROUND

Immersion cooling is an advanced method used to cool servers and other high-performance computing equipment. This technique involves submerging computer components or entire servers in a thermally conductive, but electrically insulating, liquid coolant. Unlike traditional air cooling or liquid cooling systems that use water blocks and radiators, immersion cooling directly exposes the components to the liquid, which has superior heat-absorbing properties.

### BRIEF DESCRIPTION OF THE SEVERAL VIEWS OF THE DRAWINGS

To easily identify the discussion of any particular element or act, the most significant digit or digits in a reference number refer to the figure number in which that element is first introduced.

### BRIEF DESCRIPTION OF THE DRAWINGS

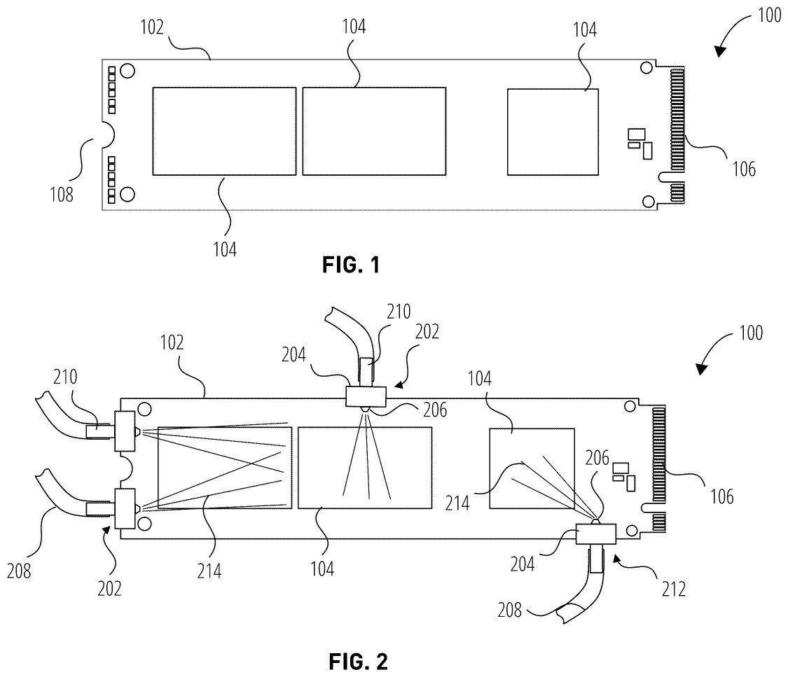

FIG. 1 is a plan view of a printed circuit board, according to some examples.

FIG. 2 is a plan view of a memory device including a PCB, SMT devices, and coolant outlets, according to some examples.

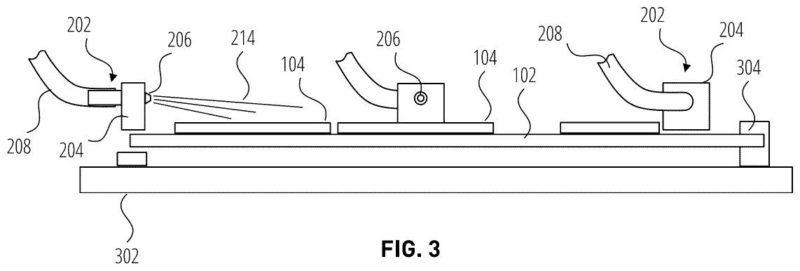

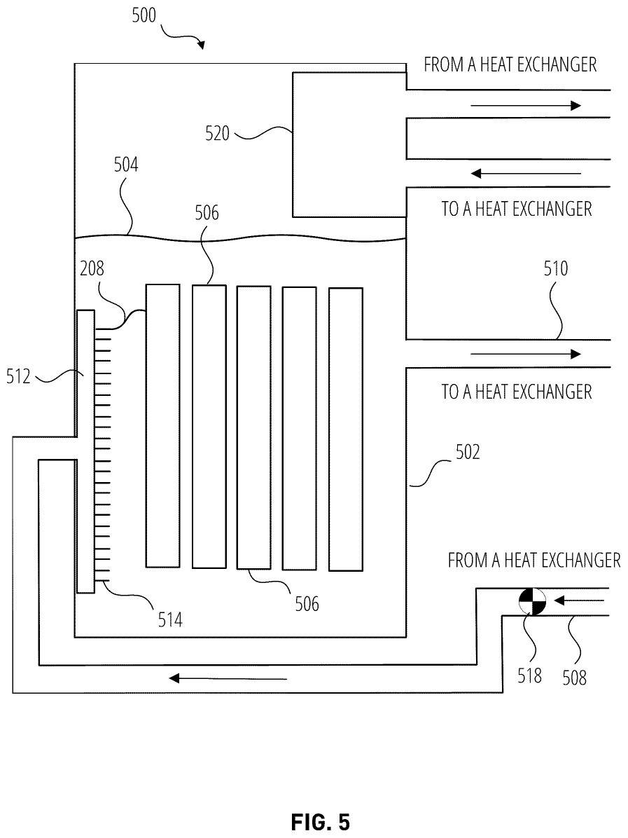

FIG. 3 is a side view of the memory device of FIG. 5, according to some examples.

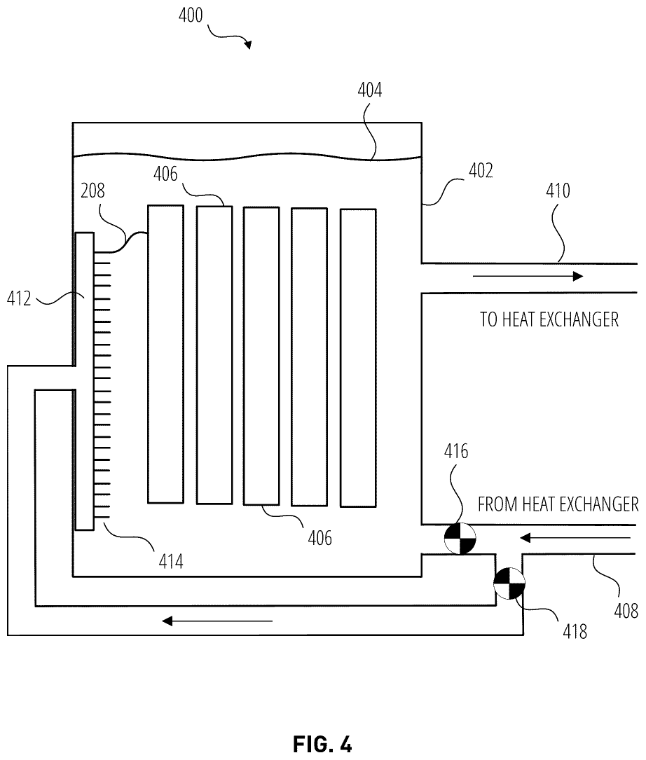

FIG. 4 is a schematic diagram illustrating a single-phase immersion cooling system, according to some examples.

FIG. 5 is a schematic diagram illustrating a single-phase immersion cooling system, according to some examples.

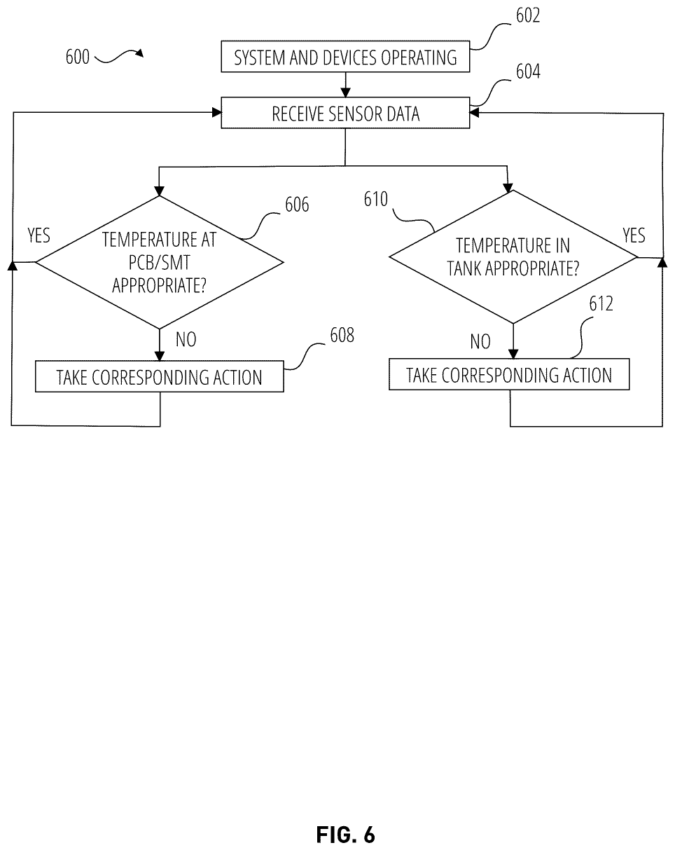

FIG. 6 is a flowchart of a method of operating the immersion cooling systems of FIG. 4 or FIG. 5, in some examples.

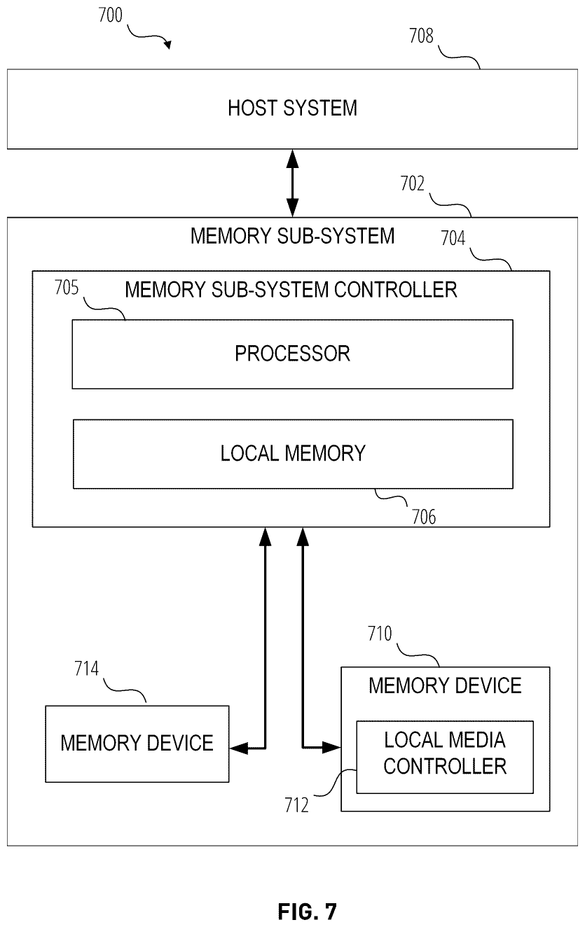

FIG. 7 is a block diagram illustrating a computing environment used to perform the methods or control the systems described herein.

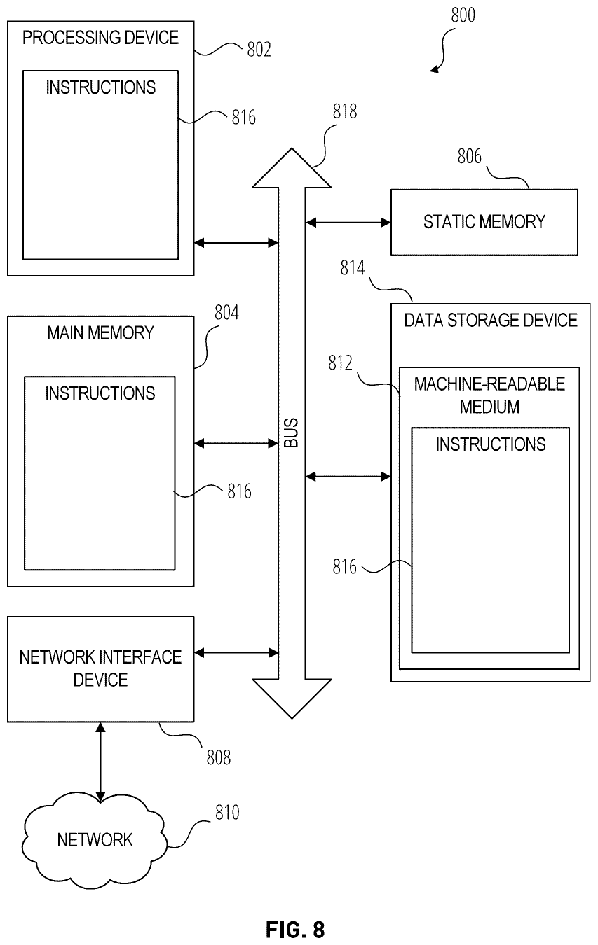

FIG. 8 illustrates an example machine in the form of a computer system within which a set of instructions can be executed to cause the machine to perform any one or more of the methods discussed herein.

### DETAILED DESCRIPTION

Servers or components to be cooled by immersion cooling are placed inside a specially designed tank or container. This tank is then filled with a dielectric coolant, which is non-conductive and will not cause short circuits or electrical damage to the components. As the server components operate and generate heat, the heat is directly transferred to the surrounding liquid. The liquid has a much higher capacity to absorb and transfer heat compared to air, making it an efficient cooling medium.

The heated liquid naturally rises and is replaced by cooler liquid in a convection cycle, or it is actively pumped through a heat exchanger. The heat exchanger removes the heat from the liquid, which is then recirculated back into the tank. The heat exchanger often transfers the absorbed heat to a secondary cooling system, which could be a water loop or an external cooling unit, where it is finally dissipated away from the computing equipment.

The benefits of immersion cooling include the ability to handle higher heat loads more efficiently than air cooling, making it suitable for high-density computing environments like data centers, reduced the energy consumption associated with air cooling, lower noise levels, and the potential of extending the lifespan of the hardware.

In single-phase immersion cooling, electronic components are submerged in a non-conductive liquid that remains in a liquid state throughout the cooling process. The liquid absorbs the heat generated by the components, and natural convection or pumps circulate the liquid to transfer the heat away from the components. The heated liquid is then cooled using a heat exchanger and recirculated back into the system.

Dual-phase immersion cooling also involves submerging components in a dielectric liquid. However, in this method, the liquid is chosen for its low boiling point, allowing it to boil when it comes into contact with the hot components. The phase change from liquid to vapor effectively absorbs a significant amount of heat. A condenser mechanism is provided above the liquid coolant level, such as a cooled surface or coil. This condenser is maintained at a lower temperature, often by running a secondary coolant or water through it. When the vapor comes into contact with the cooler surface of the condenser, it releases its latent heat and changes phase back into a liquid and drips or flows back into the immersion tank. This creates a closed-loop cooling cycle where the coolant continuously evaporates and condenses, effectively transferring heat away from the electronic components.

In both single-phase and two-phase immersion cooling system, the coolant inlet and outlet and the coolant flows therethrough are designed for functioning at the overall tank level rather than for functioning at the individual data-center module level, or for the cooling of key high-temperature devices. This can result in static or low flow rates coolant near high temperature devices, providing less-efficient heat dissipation.

Disclosed herein is a memory device including a printed circuit board (PCB), memory components and processing devices. The memory device further includes one or more coolant outlets coupled to the PCB. The coolant outlets are located so that nozzles of the coolant outlets will direct coolant flows at Surface Mount Technology (SMT) devices located on the PCB. Also disclosed is an immersion cooler including a manifold and tubing to connect the coolant outlets to a supply of pressurized coolant.

FIG. 1 is a plan view of a memory device 100 including a PCB 102 and one or more SMT devices 104 mounted on the PCB 102, according to some examples. The PCB 102 includes an M.2 connector 106 at one end thereof and a screw notch 108 at the other end thereof. One or more SMT devices 104 are mounted on the PCB 102. As used herein, the term surface-mounted device refers to any digital or analog processing or memory device coupled to a printed surface board, whether by Surface Mount Technology, Through-Hole-Technology (THT), a mix of SMT and TMT, Chip-on-Board (COB), Flip Chip, Through-Silicon Via (TSV) technology, and so forth. In some examples, the SMT device 104 is a memory sub-system, such as the memory sub-system 702 described below with reference to FIG. 7, which may be implemented as a data center Solid-State Device (SSD) system. Datacenter SSD systems can have very high workloads, for example, when used for AI applications, creating a lot of heat.

The surface-mounted devices include conventional semiconductor device packaging, such as molded plastic packages, ceramic packages, Chip-On-Board packaging, and so forth. As used herein, the term SMT device thus refers to both a single semiconductor package including multiple processors and/or memory devices, as well as to a semiconductor package including a single processor or memory device.

FIG. 2 is a plan view of a memory device 100 including a PCB 102, SMT devices 104, and coolant outlets 202, according to some examples. The coolant outlets 202 are mounted on or around the PCB 102 at relevant locations at or adjacent to SMT devices 104, to deliver cooling fluid (gas or liquid) to one or more of the SMT devices 104. Each coolant outlet 202 includes a spray block 204, a nozzle 206 and an adapter 210 for connecting the coolant outlet 202 to a tube 208 that supplies pressurized cooling fluid to the coolant outlet 202 in use.

The coolant outlets 202 deliver cooling fluid into an immersion tank, which itself contains coolant fluid, thus provide movement of the existing coolant fluid in the immersion tank over the SMT devices 104, without needing (but not excluding) modification of the SMT devices 104 or the provision of other structures such as an enclosure over each of the SMT devices 104 into which cooling fluid is delivered. The coolant outlets 212 thus provide a relatively simple and non-invasive way of providing movement of coolant fluid in the ambient environment around the SMT devices 104 that is provided by an immersion tank system.

The coolant outlets 202 in some examples are provided in different versions with fixed nozzles 206 facing in different directions, to permit variability in the mounting location of a particular coolant outlet 202 relative to an SMT device 104 that is to be cooled, as can be seen for coolant outlet 212. In other examples, the nozzles 206 are adjustable, so that the direction of a particular nozzle 206 can be set prior to installation.

FIG. 3 is a plan view of the memory device 100 of FIG. 2, according to some examples. As can be seen, in use the PCB 102 is mounted to a backplanes 302 by insertion of the M.2 connector 106 into an M.2 socket 304 on the backplane 302, and a screw located in the screw notch 108. The coolant outlets 202 are mounted around the periphery of the PCB 102, with their nozzles 206 facing inward towards the PCB 102.

In use, the memory device 100 or the backplane 302 including the memory device 100 is mounted into a server or other data processing installation, and the adapters 210 are connected to a source of pressurized cooling fluid. Operating SMT devices 104 can then receive additional cooling from cooling fluid delivered from the nozzles 206. In some examples, the speed and amount of cooling fluid that is being delivered can be controlled to provide supplemental cooling if and as needed, with the pressure of the coolant fluid that is delivered to the coolant outlets 202 (and thus the speed of the delivered cooling fluid 214) depending on the temperature of the SMT devices 104, the PCB 102, or of coolant fluid in the vicinity of the PCB 102, with the pressure being increased in response to higher temperatures and vice versa.

FIG. 4 is a schematic diagram illustrating a single-phase immersion cooling system 400, according to some examples, in which the memory devices 100 disclosed in FIG. 2 and FIG. 3 can be cooled. Electronic devices including memory devices 100, such as servers 406, are submerged in a tank 402 containing non-conductive cooling liquid 404 that remains in a liquid state throughout the cooling process. The cooling liquid 404 absorbs the heat generated by the devices, and natural convection or pumps move the liquid to transfer heat away from the devices. The heated liquid is then cooled using a heat exchanger and recirculated back into the system.

One or more manifolds 412 are provided to enable connection of the adapters 210 of the coolant outlets 202 of the memory devices 100 such that the coolant outlets 202 are coupled to, and form part of, a fluid circulation path including a supply pipe 408, the tank 402 and a return pipe 410. The supply pipe 408 and the return pipe 410 are coupled to a pump (not shown) for circulating the cooling liquid 404 through the tank 402 and a heat exchanger (not shown) for cooling the cooling liquid 404.

A tank valve 416 is provided to control the flowrate of the cooling fluid directly into the tank 402 from the supply pipe 408, while one or more manifold valves 418 are provided to control the flowrate of the fluid to the one or more manifolds 412 and thus to the coolant outlets 202 located on the PCBs 102. Each manifold 412 includes a number of spigots 414 to which tubes 208 are coupled to deliver fluid from the manifold 412 to the memory device 100. For purposes of clarity, only one tube 208 is illustrated in FIG. 4.

In some examples, each manifold 412 of the one or more manifolds has its own manifold valve 418, so that the delivery of cooling liquid 404 to each manifold 412 can be controlled, thereby to permit delivery of cooling liquid 404 to individual servers 406 or particular sets of SMT devices 104. In some examples, each spigot 414 is provided with a valve, to permit finer adjustment of delivery of cooling liquid 404 to individual SMT devices 104 or memory devices 100.

The tank valve 416, the one or more manifold valves 418, and spigot valves (if any) are operable under computer control between fully open and fully closed, and increments therebetween.

In some examples, a one-to-one connection is provided between each spigot 414 and each adapter 210, but various options are possible, including the tubes 208 branching between a spigot 414 to supply more than one coolant outlet 202, 212, or more than one spigot 414 supplying a particular coolant outlet 202, 212 if additional coolant flow is required in a particular implementation.

FIG. 5 is a schematic diagram illustrating a dual-phase immersion cooling system 500, according to some examples, in which the memory devices 100 disclosed in FIG. 2 and FIG. 3 can be cooled. Electronic devices including the memory devices 100, such as servers 506, are submerged in a tank 502 containing non-conductive cooling liquid 504. However, in this system, the liquid is chosen for its low boiling point, allowing it to boil when it comes into contact with the heat-generating components. The phase change from liquid to vapor effectively absorbs a significant amount of heat.

A condenser 520, such as a coil or cooled surface, is provided above the cooling liquid 504. The condenser is maintained at a lower temperature, often by running a secondary coolant or water through it, which in turn releases the heat it has gained in another heat exchanger (not shown). When the vapor comes into contact with the cooler surface of the condenser 520, it releases its latent heat and changes phase back into a liquid and drips or flows back into the tank 502. This creates a closed-loop cooling cycle where the cooling liquid 504 continuously evaporates and condenses, effectively transferring heat away from the electronic components.

As with the immersion cooling system 400 of FIG. 4, one or more manifolds 512 are provided to enable connection of the adapters 210 of the coolant outlets 202 of the memory devices 100 such that the coolant outlets 202 are coupled to, and form part of, a fluid circulation path including a supply pipe 508, the tank 502 and a return pipe 510. The supply pipe 508 and the return pipe 510 are coupled to a pump (not shown) for circulating the cooling liquid 504 through the tank 502 and a heat exchanger (not shown) for cooling the cooling liquid 504.

One more manifold valves 518 are provided to control the flowrate of the cooling liquid 504 to the one or more manifolds 512 and thus to the coolant outlets 202 located on the PCBs 102. Each manifold 512 includes a number of spigots 514 to which tubes 208 are coupled to deliver fluid from the manifold 512 to the memory device 100. For purposes of clarity, only one tube 208 is illustrated in FIG. 5. In some examples, each manifold 512 of the one or more manifolds has its own manifold valve 518, so that the delivery of cooling liquid 504 to each manifold 512 can be controlled, thereby to permit delivery of cooling liquid 504 to individual servers 506 or particular sets of SMT devices 104. In some examples, each spigot 514 is provided with a valve, to permit finer adjustment of delivery of cooling liquid 504 to individual SMT devices 104 or memory devices 100.

In some examples, a one-to-one connection is provided between each spigot 514 and each adapter 210, but various options are possible, including the tubes 208 branching between a spigot 514 to supply more than one coolant outlet 202, 212, or more than one spigot 514 supplying a particular coolant outlet 202, 212 if additional coolant flow is required in a particular implementation.

The one or more manifold valves 418, and spigot valves (if any) are operable under computer control between fully open and fully closed, and increments therebetween.

FIG. 6 is a flowchart 600 of a method of operating the immersion cooling systems 400, 500 in some examples. The flowchart 600 can be performed with the assistance of processing logic that can include hardware (e.g., processing device, circuitry, dedicated logic, programmable logic, microcode, hardware of a device, integrated circuit, etc.), software (e.g., instructions run or executed on a processing device), or a combination thereof. The processing logic, such as computing environment 700 or computer system 800, performs the method based on signals or data received from sensors such as temperature sensors, flowrate sensors, and so forth, and provides control instructions to individually controllable devices such as tank valves, manifold valves, and/or spigot valves as discussed above. In some examples the temperature sensors are located in the tank 402, 502, and at or on the memory devices 100 or SMT devices 104.

In some examples a group of temperature sensors may correspond to one or more memory devices 100 or SMT devices 104 that are associated with a controllable flow of cooling liquid 404, such as particular servers 406, memory devices 100 or SMT devices 104 that are associated with a particular manifold 412 that is controlled by a particular manifold valve 418 (if there is more than one manifold 412) or with a set of coolant outlets 202 associated with a controllable spigot 414 or group of spigots 414. The allocation of sets of memory devices 100 or SMT devices 104 to group together is a matter of design choice, and can depend on various factors such as providing controllable coolant fluid flow to one or more individual devices (such as servers 406) or to SMT devices 104 or memory devices 100 across multiple devices, which have a particular need for supplemental cooling.

Although shown in a particular sequence or order, unless otherwise specified, the order of the operations can be modified. Thus, the illustrated examples should be understood only as examples, and the illustrated method can be performed in a different order, and some operations can be performed in parallel. Additionally, one or more operations can be omitted in various examples. Thus, not all operations are used in every example. Other process flows are possible. The flowcharts 600 is described with reference to the immersion cooling system 400, with differences noted as appropriate.

The flowchart 600 commences at operation 602 with the immersion cooling system 400 operating and the computing devices, such as servers 406. In the case of immersion cooling system 400, cooling liquid 404 is being circulated generally through the tank 402 via supply pipe 408, tank valve 416 and return pipe 410 from and to a heat exchanger and by pump. In the case of immersion cooling system 500, cooling fluid is being circulated through condenser 520 from and to a heat exchanger by a pump.

In operation 604, data is received by the processing logic, including temperature data from temperature sensors located at individual memory devices 100, SMT devices 104 or servers 406, and a temperature sensor located in the tank 402.

At operation 606, the processing logic determines if the temperature at a zone, such as at individual or multiple memory devices 100 or at SMT devices 104 corresponding to a temperature sensor or group of temperature sensors is appropriate. If yes, the flowchart 600 returns to operation 604 and proceeds from there.

If the processing logic determines that the temperature reported by the temperature sensors in not appropriate in operation 606, the appropriate action is taken at operation 608. Examples of appropriate actions include opening or further opening by degrees a manifold valve 418 or spigot valve corresponding to the relevant temperature sensor(s) if the temperature is too high, closing or partially closing by degrees a manifold valve 418 or spigot valve corresponding to the relevant temperature sensor(s) if the temperature is too low, reporting an alarm condition, or taking other remedial action if the temperature is outside normal operating limits. The method then returns to operation 604 and continues from there.

In parallel with these operations, in operation 610, data is received by the processing logic, including temperature data from one or more temperature sensors located in the tank 402. At operation 612, the processing logic determines if the temperature in the tank 502 as reported by the temperature sensor or group of temperature sensors in the tank 402 is appropriate. If yes, the flowchart 600 returns to operation 604 and proceeds from there.

If the processing logic determines that the temperature reported in the tank 402 in not appropriate in operation 610, the appropriate action is taken at operation 610. In the case of immersion cooling system 400, examples of appropriate actions include opening or further opening by degrees tank valve 416 if the temperature is too high, closing or partially closing the tank valve 416 by degrees if the temperature is too low. In the case of both immersion cooling systems 400, 500, the appropriate action in some examples includes reporting an alarm condition or taking other remedial action if the temperature is outside normal operating limits. The method then returns to operation 604 and continues from there.

In view of the disclosure above, various examples are set forth below. It should be noted that one or more features of an example, taken in isolation or combination, should be considered within the disclosure of this application.

Example 1 is a memory device comprising: a printed circuit board; a plurality of memory components of a memory sub-system, the memory components being mounted on the printed circuit board; one or more processing devices mounted to the printed circuit board, the one or more processing devices being coupled to the memory components; and one or more coolant outlets coupled to the printed circuit board to deliver coolant to an ambient environment of the printed circuit board in the vicinity of the one or more processing devices.

In Example 2, the subject matter of Example 1 includes, wherein the one or more coolant outlets comprise nozzles directed at the one or more processing devices.

In Example 3, the subject matter of Example 2 includes, wherein the nozzles are adjustable.

In Example 4, the subject matter of Examples 2-3 includes, wherein the coolant outlets are mounted to a periphery of the printed circuit board with the nozzles directed towards the printed circuit board.

In Example 5, the subject matter of Examples 1˜4 includes, wherein the coolant outlets each comprise an adapter to receive a coolant tube.

In Example 6, the subject matter of Examples 1-5 includes, wherein the memory device comprises a data center solid-state device.

Example 7 is a system for cooling electronic devices, the system comprising: a tank for receiving a coolant liquid into which the electronic devices can be immersed in use; and a manifold comprising a fluid inlet coupleable to a supply of pressurized coolant and a plurality of spigots to deliver coolant liquid to coolant outlets located at or on the electronic devices.

In Example 8, the subject matter of Example 7 includes, a valve for controlling delivery of coolant fluid from the manifold.

In Example 9, the subject matter of Example 8 includes, control logic operable to control a degree of opening of the valve based on a temperature measurements obtained at least one temperature sensor located in the tank.

In Example 10, the subject matter of Examples 8-9 includes, wherein the valve comprises a plurality of valves, each one of the plurality of valves being controllable to deliver fluid to one or more selected memory devices included in the electronic devices.

In Example 11, the subject matter of Example 10 includes, control logic operable to control a degree of opening of each of the valves based on a temperature measurements obtained from zones in the tank, each zone corresponding to a particular valve.

In Example 12, the subject matter of Examples 7-11 includes, a plurality of manifolds.

In Example 13, the subject matter of Example 12 includes, valves for independently controlling delivery of coolant fluid from each of the plurality of manifolds.

In Example 14, the subject matter of Example 13 includes, control logic operable to control a degree of opening of each of the plurality of valves based on a temperature measurements obtained from zones in the tank.

In Example 15, the subject matter of Examples 11-14 includes, wherein the coolant outlets deliver coolant to an ambient environment of a printed circuit board in the vicinity of one or more processing devices.

Example 16 is a method of operating an immersion cooler comprising a tank including coolant liquid in which memory devices are immersed, a manifold including a fluid inlet coupled to a supply of pressurized coolant and a plurality of spigots to deliver coolant liquid to coolant outlets located at or on the memory devices, the method comprising: operating surface-mounted devices located on the memory devices; detecting a temperature at a particular memory device; determining if the temperature is appropriate; and based on the temperature not being appropriate, adjusting a valve to vary delivery of coolant liquid to an ambient environment of the particular memory device.

In Example 17, the subject matter of Example 16 includes, wherein the immersion cooler comprises a plurality of manifolds, each manifold having associated therewith a controllable valve to vary the delivery of coolant liquid from that manifold.

In Example 18, the subject matter of Examples 16-17 includes, wherein the manifold includes a plurality of controllable valves to control the delivery of coolant liquid from different groups of spigots on the manifold.

In Example 19, the subject matter of Examples 16-18 includes, wherein the memory devices comprise a printed circuit board and one or more processors, the plurality of spigots being located at a periphery of each printed circuit board and directed at the processors.

In Example 20, the subject matter of Examples 16-19 includes, wherein the memory devices comprise data center solid-state devices.

Example 21 is at least one machine-readable medium including instructions that, when executed by processing circuitry, cause the processing circuitry to perform operations to implement of any of Examples 1-20. Example 22 is an apparatus comprising means to implement of any of Examples 1-20. Example 23 is a system to implement of any of Examples 1-20. Example 24 is a method to implement of any of Examples 1-20.

FIG. 7 is a block diagram illustrating a computing environment 700 used to perform or control the methods and systems described herein. The computing environment 700 includes a host system 708 that is coupled to one or more memory sub-systems 702. In some examples, the host system 708 is coupled to different types of memory sub-system 702. FIG. 7 illustrates one example of a host system 708 coupled to one memory sub-system 702. The host system 708 uses the memory sub-system 702, for example, to write data to the memory sub-system 702 and read data from the memory sub-system 702. As used herein, “coupled to” generally refers to a connection between components, which can be an indirect communicative connection or direct communicative connection (e.g., without intervening components), whether wired or wireless, including connections such as electrical, optical, magnetic, etc.

The memory sub-system 702 can include media, such as one or more volatile memory devices (e.g., memory device 714), one or more non-volatile memory devices (e.g., memory device 710), or a combination of such. A printed circuit board of an example can implement one or more of the memory device 710, the memory device 714, a memory sub-system controller 704, or the memory sub-system 702. The memory sub-system 702 can be a storage device, a memory module, or a hybrid of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, and a hard disk drive (HDD). Examples of memory modules include a dual in-line memory module (DIMM), a small outline DIMM (SO-DIMM), and a non-volatile dual in-line memory module (NVDIMM).

The host system 708 can be a computing device such as a desktop computer, laptop computer, video game console, network server, mobile device, embedded computer (e.g., one included in a vehicle, industrial equipment, or a networked commercial device), or such computing device that includes a memory and a processing device. The host system 708 can be coupled to the memory sub-system 702 via a physical host interface. Examples of a physical host interface include, but are not limited to, a serial advanced technology attachment (SATA) interface, a peripheral component interconnect express (PCIe) interface, universal serial bus (USB) interface, Fiber Channel, Serial Attached SCSI (SAS), etc. The physical host interface can be used to transmit data between the host system 708 and the memory sub-system 702. The host system 708 can further utilize an NVM Express (NVMe) interface to access the memory components (e.g., memory devices 710) when the memory sub-system 702 is coupled with the host system 708 by the PCIe interface. The physical host interface can provide an interface for passing control, address, data, and other signals between the memory sub-system 702 and the host system 708.

The memory devices can include any combination of the different types of non-volatile memory devices and/or volatile memory devices. The volatile memory devices (e.g., memory device 714) can be, but are not limited to, random access memory (RAM), such as dynamic random access memory (DRAM) and synchronous dynamic random access memory (SDRAM).

An example of non-volatile memory devices (e.g., memory device 710) includes a negative-and (NAND) type flash memory. Each of the memory devices 710 can include one or more arrays of memory cells such as single-level cells (SLCs) or multi-level cells (MLCs) (e.g., triple-level cells (TLCs) or quad-level cells (QLCs)). In some examples, a particular memory component can include an SLC portion, and an MLC portion, a TLC portion, or a QLC portion of memory cells. Each of the memory cells can store one or more bits of data used by the host system 708. Furthermore, the memory cells of the memory devices 710 can be grouped as memory pages or memory blocks that can refer to a unit of the memory component used to store data.

Although non-volatile memory components such as NAND type flash memory are described, the memory device 710 can be based on any other type of non-volatile memory, such as read-only memory (ROM), phase change memory (PCM), magneto random access memory (MRAM), negative-or (NOR) flash memory, electrically erasable programmable read-only memory (EEPROM), and a cross-point array of non-volatile memory cells. A cross-point array of non-volatile memory can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased.

The memory sub-system controller 704 can communicate with the memory devices 710 to perform operations such as reading data, writing data, or erasing data at the memory devices 710 and other such operations. The memory sub-system controller 704 can include hardware such as one or more integrated circuits and/or discrete components, a buffer memory, or a combination thereof. The memory sub-system controller 704 can be a microcontroller, special purpose logic circuitry (e.g., a field programmable gate array (FPGA), an application specific integrated circuit (ASIC), etc.), or other suitable processor.

The memory sub-system controller 704 can include a processor (processing device 705 configured to execute instructions stored in local memory 706. In the illustrated example, the local memory 706 of the memory sub-system controller 704 includes an embedded memory configured to store instructions for performing various processes, operations, logic flows, and routines that control operation of the memory sub-system 702, including handling communications between the memory sub-system 702 and the host system 708.

In some examples, the local memory 706 can include memory registers storing memory pointers, fetched data, etc. The local memory 706 can also include read-only memory (ROM) for storing micro-code. While the example memory sub-system 702 in FIG. 7 has been illustrated as including the memory sub-system controller 704, in another example of the present disclosure, a memory sub-system 702 may not include a memory sub-system controller 704, and may instead rely upon external control (e.g., provided by an external host, or by a processor or controller separate from the memory sub-system).

In general, the memory sub-system controller 704 can receive commands or operations from the host system 708 and can convert the commands or operations into instructions or appropriate commands to achieve the desired access to the memory devices 710. The memory sub-system controller 704 can be responsible for other operations such as wear leveling operations, garbage collection operations, error detection and error-correcting code (ECC) operations, encryption operations, caching operations, and address translations between a logical block address and a physical block address that are associated with the memory devices 710. The memory sub-system controller 704 can further include host interface circuitry to communicate with the host system 708 via the physical host interface. The host interface circuitry can convert the commands received from the host system into command instructions to access the memory devices 710 as well as convert responses associated with the memory devices 710 into information for the host system 708.

The memory sub-system 702 can also include additional circuitry or components that are not illustrated. In some examples, the memory sub-system 702 can include a cache or buffer (e.g., DRAM) and address circuitry (e.g., a row decoder and a column decoder) that can receive an address from the memory sub-system controller 704 and decode the address to access the memory devices 710.

In some examples, the memory devices 710 include local media controllers 712 that operate in conjunction with memory sub-system controller 704 to execute operations on one or more memory cells of the memory devices 710.

FIG. 8 illustrates an example machine in the form of a computer system 800 within which a set of instructions can be executed for causing the machine to perform any one or more of the methods discussed herein. In some examples, the computer system 800 can correspond to a host system (e.g., the host system 708 of FIG. 7) that includes, is coupled to, or utilizes a memory sub-system (e.g., the memory sub-system 702 of FIG. 7) or can be used to perform the operations described herein. In alternative examples, the machine can be connected (e.g., networked) to other machines in a local area network (LAN), an intranet, an extranet, and/or the Internet. The machine can operate in the capacity of a server or a client machine in a client-server network environment, as a peer machine in a peer-to-peer (or distributed) network environment, or as a server or a client machine in a cloud computing infrastructure or environment.

The machine can be a personal computer (PC), a tablet PC, a Mini PC, a laptop, a video game console, a set-top box (STB), a personal digital assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methods discussed herein.

The example computer system 800 includes a processing device 802, a main memory 804 (e.g., read-only memory (ROM), flash memory, dynamic random access memory (DRAM) such as synchronous DRAM (SDRAM) or Rambus DRAM (RDRAM), etc.), a static memory 806 (e.g., flash memory, static random access memory (SRAM), etc.), and a data storage device 814, which communicate with each other via a bus 818.

The processing device 802 represents one or more general-purpose processing devices such as a microprocessor, a central processing unit, or the like. More particularly, the processing device 802 can be a complex instruction set computing (CISC) microprocessor, a reduced instruction set computing (RISC) microprocessor, a very long instruction word (VLIW) microprocessor, a processor implementing other instruction sets, or processors implementing a combination of instruction sets. The processing device 802 can also be one or more special-purpose processing devices such as an application specific integrated circuit (ASIC), a field programmable gate array (FPGA), a digital signal processor (DSP), a network processor, or the like. The processing device 802 is configured to execute instructions 816 for performing the operations and steps discussed herein. The computer system 800 can further include a network interface device 808 to communicate over a network 810.

The data storage device 814 can include a machine-readable storage medium 812 (also known as a computer-readable medium) on which is stored one or more sets of instructions 816 or software embodying any one or more of the methods or functions described herein. The instructions 816 can also reside, completely or at least partially, within the main memory 804 and/or within the processing device 802 during execution thereof by the computer system 800, the main memory 804 and the processing device 802 also constituting machine-readable storage media. The machine-readable storage medium 812, data storage device 814, and/or main memory 804 can correspond to the memory sub-system 702 of FIG. 7.

In one example, the instructions 816 include instructions to implement functionality as described above. While the machine-readable storage medium 812 is shown, in some examples, to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methods of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer-readable storage medium, such as, but not limited to, any type of disk including floppy disks, optical disks, CD-ROMs, and magnetic-optical disks, read-only memories (ROMs), random access memories (RAMs), EPROMS, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some examples, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

The foregoing disclosure describes specific example implementations. It will be evident that various modifications can be made thereto without departing from the broader spirit and scope of examples of the disclosure as set forth in the following claims. The specification and drawings are, accordingly, to be regarded in an illustrative sense rather than a restrictive sense.

What is claimed is:

1. A memory device comprising:
a printed circuit board;
a plurality of memory components of a memory sub-system, the memory components being mounted on the printed circuit board;
one or more processing devices mounted to the printed circuit board, the one or more processing devices being coupled to the memory components; and
one or more coolant outlets coupled to the printed circuit board to deliver coolant to an ambient environment of the printed circuit board in the vicinity of the one or more processing devices.

2. The memory device of claim 1, wherein the one or more coolant outlets comprise nozzles directed at the one or more processing devices.

3. The memory device of claim 2, wherein the nozzles are adjustable.

4. The memory device of claim 2, wherein the coolant outlets are mounted to a periphery of the printed circuit board with the nozzles directed towards the printed circuit board.

5. The memory device of claim 1, wherein the coolant outlets each comprise an adapter to receive a coolant tube.

6. The memory device of claim 1, wherein the memory device comprises a data center solid-state device.

7. A system for cooling electronic devices, the system comprising:
a tank for receiving a coolant liquid into which the electronic devices can be immersed in use; and
a manifold comprising a fluid inlet coupleable to a supply of pressurized coolant and a plurality of spigots to deliver coolant liquid to coolant outlets located at or on the electronic devices.

8. The system of claim 7, further comprising a valve for controlling delivery of coolant fluid from the manifold.

9. The system of claim 8, further comprising control logic operable to control a degree of opening of the valve based on a temperature measurements obtained at least one temperature sensor located in the tank.

10. The system of claim 8, wherein the valve comprises a plurality of valves, each one of the plurality of valves being controllable to deliver fluid to one or more selected memory devices included in the electronic devices.

11. The system of claim 10, further comprising control logic operable to control a degree of opening of each of the valves based on a temperature measurements obtained from zones in the tank, each zone corresponding to a particular valve.

12. The system of claim 7, comprising a plurality of manifolds.

13. The system of claim 12, further comprising valves for independently controlling delivery of coolant fluid from each of the plurality of manifolds.

14. The system of claim 13, further comprising control logic operable to control a degree of opening of each of the plurality of valves based on a temperature measurements obtained from zones in the tank.

15. The system of claim 11, wherein the coolant outlets deliver coolant to an ambient environment of a printed circuit board in the vicinity of one or more processing devices.

16. A method of operating an immersion cooler comprising a tank including coolant liquid in which memory devices are immersed, a manifold including a fluid inlet coupled to a supply of pressurized coolant and a plurality of spigots to deliver coolant liquid to coolant outlets located at or on the memory devices, the method comprising:
operating surface-mounted devices located on the memory devices;
detecting a temperature at a particular memory device;
determining if the temperature is appropriate; and
based on the temperature not being appropriate, adjusting a valve to vary delivery of coolant liquid to an ambient environment of the particular memory device.

17. The method of claim 16 wherein the immersion cooler comprises a plurality of manifolds, each manifold having associated therewith a controllable valve to vary the delivery of coolant liquid from that manifold.

18. The method of claim 16 wherein the manifold includes a plurality of controllable valves to control the delivery of coolant liquid from different groups of spigots on the manifold.

19. The method of claim 16, wherein the memory devices comprise a printed circuit board and one or more processors, the plurality of spigots being located at a periphery of each printed circuit board and directed at the processors.

20. The method of claim 16, wherein the memory devices comprise data center solid-state devices.
